(19) United States
(12) Patent Application Publication
(10) Pub. No.: US 2024/0222343 A1
(43) Pub. Date: Jul. 4, 2024

(54) DISPLAY DEVICE

(71) Applicant: LG Display Co., Ltd., Seoul (KR)

(72) Inventors: Minseok KIM, Seoul (KR); Jongsung KIM, Seoul (KR); Yongmin HA, Seoul (KR)

(21) Appl. No.: 18/399,132

(22) Filed: Dec. 28, 2023

(30) Foreign Application Priority Data
Dec. 30, 2022 (KR) 10-2022-0190883

(51) Int. Cl. H01L 25/16; H01L 27/12

(52) U.S. Cl. CPC H01L 25/167; H01L 27/124

(57) ABSTRACT

Disclosed is a display device including a wiring substrate in which a plurality of link wiring lines are disposed; a plurality of display units disposed on the wiring substrate and spaced apart from each other; and a plurality of bonding members positioned between the display units and the wiring substrate, wherein the plurality of bonding members are respectively connected to the plurality of link wiring lines, wherein the wiring substrate includes a thin-film transistor, wherein each of the display units includes a light-emitting element.

### CROSS-REFERENCE TO RELATED APPLICATION

This application claims priority from Korean Patent Application No. 10-2022-0190883 filed on Dec. 30, 2022 in the Korean Intellectual Property Office, and all the benefits accruing therefrom under 35 U.S.C. 119, the contents of which in its entirety are herein incorporated by reference.

### BACKGROUND

### Technical Field

The present disclosure relates to a display device, and more particularly, to a display device in which a plurality of display units are disposed on a wiring substrate on which a plurality of link wiring lines are disposed.

### Description of Related Art

A display device is applied to various electronic devices such as TVs, mobile phones, laptops and tablets. To this end, research to develop thinning, lightening, and low power consumption of the display device is continuing.

Among display devices, a light-emitting display device has a light-emitting element or a light source built therein and displays information using light generated from the built-in light-emitting element or light source. A display device including a self-light-emitting element may be implemented to be thinner than a display device with the built-in light source, and may be implemented as a flexible display device that may be folded, bent, or rolled.

The display device having the self-light-emitting element may include, for example, an organic light-emitting display device (OLED) including a light-emitting layer made of an organic material, or a micro LED display device (micro light-emitting diode display device) including a light-emitting layer made of an inorganic material. In this regard, the organic light-emitting display device does not require a separate light source. However, due to material characteristics of the organic material that is vulnerable to moisture and oxygen, a defective pixel easily occurs in the organic light-emitting display device (OLED) due to an external environment. On the contrary, the micro LED display device includes the light-emitting layer made of the inorganic material that is resistant to moisture and oxygen and thus is not affected by the external environment and thus has high reliability and has a long lifespan compared to the organic light-emitting display device.

### BRIEF SUMMARY

A technical purpose according to one embodiment of the present disclosure is to provide a large-area transparent display device in which a plurality of display units are disposed on a wiring substrate on which a plurality of link wiring lines are disposed.

Further, a technical purpose according to an embodiment of the present disclosure is to provide a display device in which a bezel area is minimum, reduced or substantially absent to realize a zero bezel area.

Further, a technical purpose according to an embodiment of the present disclosure is to provide a display device that prevents a transfer yield from being lowered in transferring a light-emitting element onto a display unit or display unit structure.

Further, a technical purpose according to an embodiment of the present disclosure is to provide a display device that prevents misalignment of a light-emitting element from occurring due to increase in the number of times of transferring of the light-emitting element on the display unit.

Further, a technical purpose according to an embodiment of the present disclosure is to provide a display device in which a defective light-emitting element or thin-film transistor can be easily repaired.

Purposes according to the present disclosure are not limited to the above-mentioned purposes. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

A first aspect of the present disclosure provides a display device comprising: a wiring substrate; a plurality of link wiring lines disposed in the wiring substrate; a plurality of display units disposed on the wiring substrate and spaced apart from each other; and a plurality of bonding members positioned between the plurality of display units and the wiring substrate, wherein the plurality of bonding members are respectively connected to the plurality of link wiring lines, wherein the wiring substrate includes a thin-film transistor, wherein each of the plurality of display units includes a light-emitting element.

In one implementation of the first aspect, the wiring substrate includes a single substrate, wherein the plurality of display units are disposed on the wiring substrate and are arranged so as to be spaced apart from each other in each of first and second directions intersecting or transverse each other.

In one implementation of the first aspect, the wiring substrate includes: a first base substrate; a light-blocking layer disposed on the first base substrate; the thin-film transistor disposed on the light-blocking layer, wherein the thin-film transistor includes a semiconductor layer, a gate electrode, a source electrode, and a drain electrode; a first via contact electrically for connecting the drain electrode and the light-blocking layer to each other; a first planarization layer covering the thin-film transistor on the first base substrate; a second via contact that extends through the first planarization layer so as to be connected to the drain electrode; a connection electrode electrically connected to the second via contact; a second planarization layer having an opening therein exposing a portion of a surface of the connection electrode; a first line electrode disposed on the second planarization layer; and a second line electrode disposed on the second planarization layer and spaced apart from the first line electrode, wherein the second line electrode extends along and on an exposed surface of the opening and is electrically connected to the drain electrode via the connection electrode.

In one implementation of the first aspect, each of the plurality of display units includes: a second base substrate made of a transparent material; a first assembly electrode disposed on the second base substrate; a second assembly electrode disposed on the second base substrate and spaced apart from the first assembly electrode; a first clad electrode covering the first assembly electrode; a second clad electrode covering the second assembly electrode; and a partitioning wall having a portion covering each of the first and second clad electrodes, and a remaining portion disposed on the second base substrate, wherein the partitioning wall includes an assembly pocket, wherein the light-emitting element is received in the assembly pocket.

In one implementation of the first aspect, a spacing between the first clad electrode and the second clad electrode is smaller than a spacing between the first assembly electrode and the second assembly electrode.

In one implementation of the first aspect, the light-emitting element is electrically connected to the first line electrode and the second line electrode of the wiring substrate.

In one implementation of the first aspect, the partitioning wall has a thickness equal to or greater than a height of the light-emitting element.

In one implementation of the first aspect, the display device further comprises a filling material disposed between the wiring substrate and the plurality of display units, wherein the filling material includes a transparent resin.

In one implementation of the first aspect, each of the bonding members includes a spacer pattern having one surface contacting the wiring substrate; a conductive connection pattern covering at least an outer side surface of the spacer pattern; and an adhesive pattern disposed on the other surface of the spacer pattern and contacting the conductive connection pattern, wherein the adhesive pattern is connected to each of the plurality of display units.

A second aspect of the present disclosure provides a display device comprising: a wiring substrate; a plurality of link wiring lines disposed in the wiring substrate; a plurality of display units disposed on the wiring substrate and spaced apart from each other; and a plurality of bonding members disposed between the display units and the wiring substrate, wherein the plurality of bonding members are respectively connected to the plurality of link wiring lines, wherein the wiring substrate includes a light-emitting element, and wherein the plurality of display units includes a thin-film transistor.

In one implementation of the second aspect, each of the plurality of display units includes: a second base substrate; a light-blocking layer disposed on the second base substrate; a thin-film transistor disposed on the light-blocking layer and including a semiconductor layer, a gate electrode, a source electrode, and a drain electrode; a first via contact for electrically connecting the drain electrode and the light-blocking layer to each other; a first planarization layer covering the thin-film transistor on the second base substrate; a second via contact that extends through the first planarization layer so as to be connected to the drain electrode; a connection electrode electrically connected to the second via contact; a second planarization layer having an opening therein exposing a portion of a surface of the connection electrode; a first line electrode disposed on the second planarization layer; and a second line electrode disposed on the second planarization layer and spaced apart from the first line electrode, wherein the second line electrode extends along and on an exposed surface of the opening and is electrically connected to the drain electrode via the connection electrode.

In one implementation of the second aspect, the wiring substrate includes: a first base substrate made of a transparent material; a first assembly electrode disposed on the first base substrate; a second assembly electrode disposed on the first base substrate and spaced apart from the first assembly electrode; a first clad electrode covering the first assembly electrode; a second clad electrode covering the second assembly electrode; and an adhesive layer disposed on each of the first and second clad electrodes so as to designate a position where the light-emitting element is disposed.

In one implementation of the second aspect, a spacing between the first clad electrode and the second clad electrode is smaller than a spacing between the first assembly electrode and the second assembly electrode.

In one implementation of the second aspect, the light-emitting element is electrically connected to the first line electrode and the second line electrode of the respective display unit.

In one implementation of the second aspect, the display device further comprises a filling material disposed between the wiring substrate and the display units, wherein the filling material includes a transparent resin.

In one implementation of the second aspect, each of the bonding members includes: a spacer pattern having one surface contacting each link wiring line of the wiring substrate; a conductive connection pattern covering an at least outer side surface of the spacer pattern; and an adhesive pattern disposed on the other surface of the spacer pattern and contacting the conductive connection pattern, wherein the adhesive pattern is connected to each of the plurality of display units.

According to the embodiment of the present disclosure, the plurality of display units may be disposed on the upper surface of the wiring substrate on which the plurality of link wiring lines are disposed so as to overlap the plurality of link wiring lines, respectively, thereby realizing an effect of realizing a large-area transparent display device.

Further, according to an embodiment of the present disclosure, the self-assembly substrate on which the light-emitting element is disposed may act as the display unit and may be directly bonded onto the wiring substrate, such that the process step of transferring the light-emitting element may be omitted, thereby realizing the effect of realizing process optimization.

Further, the self-assembly substrate on which the light-emitting element is disposed may be directly bonded to the wiring substrate, such that the use of the transfer substrate may be omitted, thereby unifying parts with each other and thus manufacturing the eco-friendly product.

Further, the self-assembly substrate on which the light-emitting element is disposed may be directly bonded to the wiring substrate, such that the process of transferring the light-emitting element on a separate display unit may be omitted, thereby preventing the decrease in the transfer yield of the light-emitting element and preventing misalignment thereof.

Further, the self-assembly substrate on which the light-emitting element is disposed may be directly bonded to the wiring substrate, such that the defective light-emitting element may be easily repaired.

Further, the display unit where the thin-film transistor is disposed may be directly bonded to the wiring substrate where the light-emitting element is disposed, thereby realizing the effect of easily repairing the defective thin-film transistor.

Further, the technical effect according to an embodiment of the present disclosure may provide the display device in which a bezel area is minimum, reduced or substantially absent to realize a zero bezel area.

Effects of the present disclosure are not limited to the effects mentioned above, and other effects not mentioned will be clearly understood by those skilled in the art from the descriptions below.

### BRIEF DESCRIPTION OF THE SEVERAL VIEWS OF THE DRAWINGS

FIG. 1 is a schematic plan view of a display device according to an embodiment of the present disclosure.

FIG. 2 is a schematic plan view of 2 of FIG. 1 of the display device according to one embodiment of the present disclosure.

FIG. 3 is a cross-sectional view of 3 in FIG. 2.

FIG. 4 is a cross-sectional view of 4 of FIG. 3 of the display device according to one embodiment of the present disclosure.

FIG. 5 is a cross-sectional view showing a modified example of a display device according to one embodiment of the present disclosure.

FIG. 6 is a schematic cross-sectional view of a region 6 of FIG. 1 of a display device according to another embodiment of the present disclosure.

FIG. 7 is a cross-sectional view of 7 of FIG. 6 of the display device according to another embodiment of the present disclosure.

### DETAILED DESCRIPTION

Advantages and features of the present disclosure, and a method of achieving the advantages and features will become apparent with reference to embodiments described later in detail together with the accompanying drawings. However, the present disclosure is not limited to the embodiments as disclosed below, but may be implemented in various different forms. Thus, these embodiments are set forth only to make the present disclosure complete, and to completely inform the scope of the present disclosure to those of ordinary skill in the technical field to which the present disclosure belongs.

A shape, a size, a ratio, an angle, a number, etc., disclosed in the drawings for describing the embodiments of the present disclosure are examples, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “including”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like may be disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like may be disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is indicated.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof.

It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

The features of the various embodiments of the present disclosure may be partially or entirely combined with each other, and may be technically associated with each other or operate with each other. The embodiments may be implemented independently of each other and may be implemented together in an association relationship.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a display device according to each embodiment of the present disclosure will be described with reference to the accompanying drawings.

A display device including a micro LED may realize a flexible display device with a thinner structure than that of an organic light-emitting display device. Accordingly, a plurality of display units including a plurality of micro LEDs are arranged to easily implement a large-area tiling display device.

A process of forming a display device including a micro LED includes growing a light-emitting element on a growth substrate, and then removing the light-emitting element from the growth substrate and transferring the light-emitting element onto a self-assembly substrate in an aligned manner using a first transfer process. The light-emitting element may be embodied as a micro LED. Next, the light-emitting element transferred onto the self-assembly substrate is transferred to a transfer substrate in an aligned manner, and then the light-emitting element on the transfer substrate is transferred to a substrate of the display device in an aligned manner in a second transfer process to manufacture the display device including the micro LED.

However, when the light-emitting element is transferred to the self-assembly substrate in the first transfer process, the light-emitting element transferred onto the self-assembly substrate is not transferred to a target position or is transferred to a position outside the target position, such that a transfer yield decreases. Further, in order to transfer the light-emitting elements emitting light of different colors, the number of transfers increases. As the number of transfers increases, the alignment accuracy of the light-emitting element deteriorates, resulting in a misalignment problem in which the light-emitting elements deviate from the target position.

However, in a display device according to an embodiment of the present disclosure, a self-assembly substrate on which a light-emitting element is disposed is embodied as a display unit or display unit structure and is directly bonded on a wiring substrate, thereby preventing the decrease in the transfer yield or the misalignment of the light-emitting element. This will be described with reference to the drawings below.

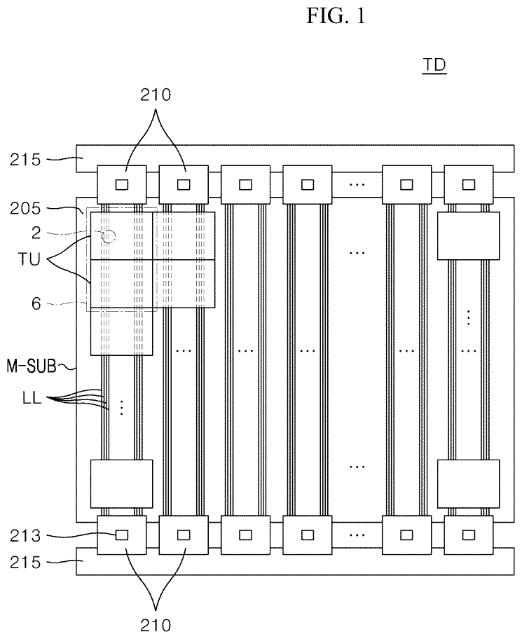

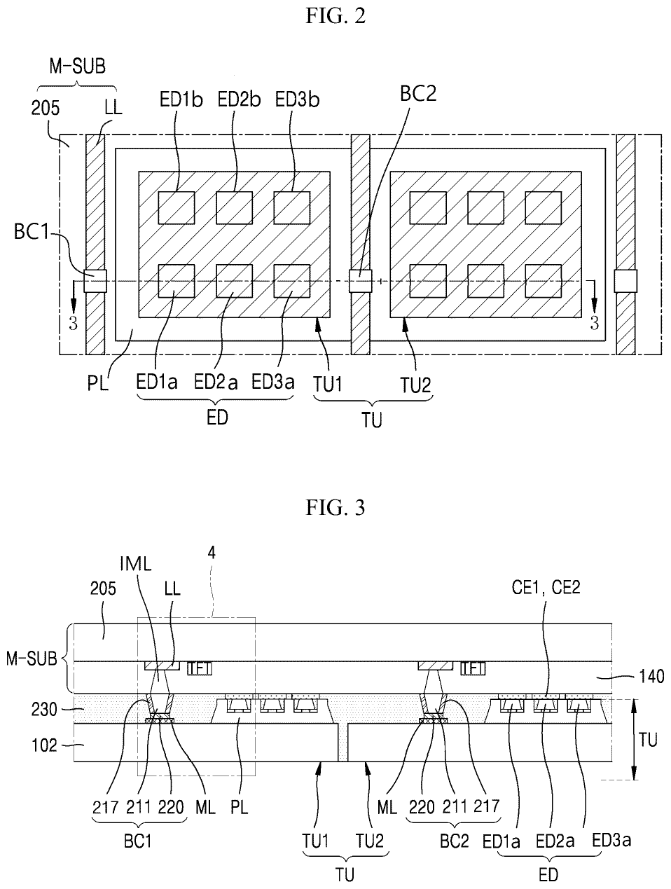

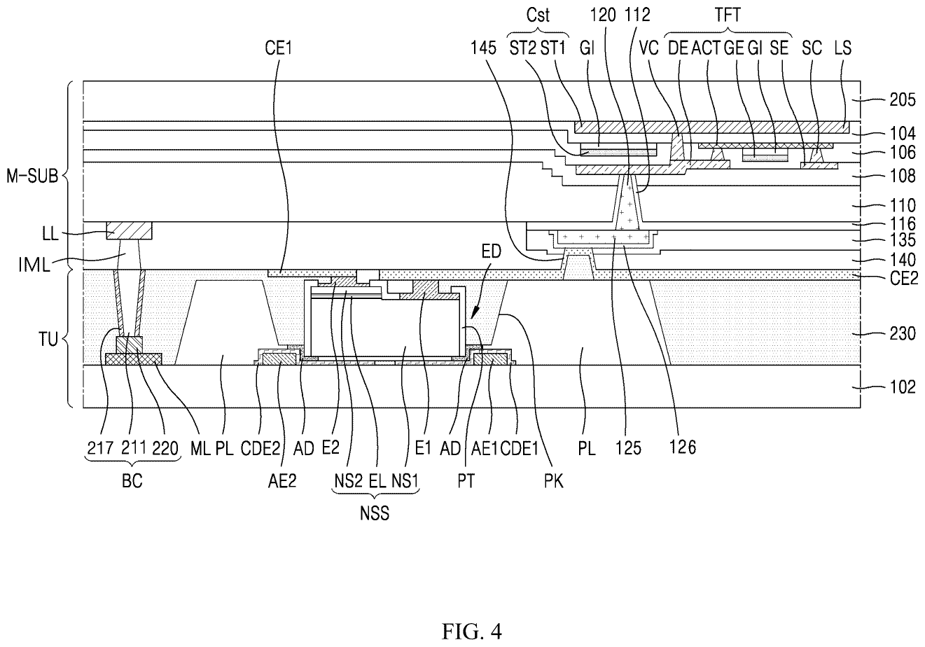

FIG. 1 is a schematic plan view of a display device according to an embodiment of the present disclosure. FIG. 2 is a schematic plan view of 2 of FIG. 1 of the display device according to one embodiment of the present disclosure. FIG. 3 is a cross-sectional view of 3 in FIG. 2. FIG. 4 is a cross-sectional view of 4 of FIG. 3 of the display device according to one embodiment of the present disclosure.

In FIG. 1, for convenience of illustration, among components of a display device TD, only a first base substrate 205 of a wiring substrate M-SUB, a plurality of link wiring lines LL disposed on the first base substrate 205, each of a plurality of circuit films 210 on which each of integrated circuit chips 213 is disposed, a printed circuit board 215, and a plurality of display units TU are shown.

Referring to FIG. 1 to FIG. 3, the tiling display device TD according to one embodiment of the present disclosure may include the plurality of display units TU arranged on the wiring substrate M-SUB. The display units TU may be arranged along a first direction and a second direction intersecting or transverse the first direction. In this regard, the first direction may be a horizontal direction, and the second direction may be a vertical direction. The wiring substrate M-SUB and the display unit TU may include glass or transparent plastic. As a result, a large-area transparent display device may be implemented.

The plurality of link wiring lines LL and a plurality of transistors TFT may be disposed on the first base substrate 205 of the wiring substrate M-SUB. The plurality of link wiring lines LL may be arranged along one direction of the first base substrate 205. A driver may be disposed on at least one side end of the wiring substrate M-SUB. The driver may include the printed circuit board 215 connected to the circuit film 210 on which the integrated circuit chip 213 is mounted. The circuit film 210 is connected to an end of the link wiring line LL. The driver may transmit various signals to sub-pixels of each display unit. For example, the signals transmitted to the sub-pixels may include a high-potential voltage, a low-potential voltage, a scan signal, or a data signal. In an embodiment of the present disclosure, a configuration in which the driver including the printed circuit board 215 connected to the circuit film 210 on which the integrated circuit chip 213 is mounted is disposed at each of both opposing ends of the wiring substrate 205 is illustrated. However, the present disclosure is not limited thereto.

The plurality of link wiring lines LL may deliver the various signals transmitted from the driver to a plurality of signal lines of each of the plurality of display units TU. For example, the signal lines may include a high-potential voltage line, a low-potential voltage line, a scan line, or a data line. Details thereof will be described later with reference to FIG. 4.

The wiring substrate M-SUB may include the thin-film transistor TFT. The thin-film transistor TFT may be electrically connected to each of a plurality of light-emitting elements ED disposed on the display unit TU and may transmit a driving signal to the light-emitting element ED such that the light-emitting element ED emits light. To this end, a first line electrode CE1 and a second line electrode CE2 electrically connected to the thin-film transistor TFT may be disposed on the wiring substrate M-SUB. The first line electrode CE1 and the second line electrode CE2 may be electrically connected to the light-emitting element ED so as to transfer the driving signal from the thin-film transistor TFT to the light-emitting element ED.

The plurality of display units TU arranged on the wiring substrate M-SUB may be connected to the first base substrate 205 via electrical connection between the plurality of signal lines and the plurality of link wiring lines LL disposed in the wiring substrate M-SUB. In this regard, the plurality of link wiring lines LL may be disposed to overlap the plurality of display units TU and may not be exposed to the outside. As a result, an area size of the circuit area where the plurality of link wiring lines LL are disposed may be reduced, so that the display area can be increased.

Referring to FIG. 2 and FIG. 3, a plurality of display units TU1 and TU2 may include the first display unit TU1 and the second display unit TU2 adjacent to each other in one direction and disposed on the wiring substrate M-SUB. In the drawing, only a configuration in which two display units TU1 and TU2 are arranged is presented for convenience of illustration. However, the present disclosure is not limited thereto. For example, another display unit may be disposed so as to be adjacent to one side of each display unit.

Each of the display units TU1 and TU2 according to one embodiment of the present disclosure may act as a self-assembly substrate on which a plurality of light-emitting elements ED is disposed.

The plurality of light-emitting elements ED may include a first light-emitting element ED1a, a second light-emitting element ED2a, and a third light-emitting element ED3a. The first light-emitting element ED1a, the second light-emitting element ED2a, and the third light-emitting element ED3a may respectively emit light of different colors. For example, the first light-emitting element ED1a may emit red (R) light, the second light-emitting element ED2a may emit green (G) light, and the third light-emitting element ED3a may emit blue (B) light. However, the present disclosure is not limited thereto, and the light-emitting element may further include a white light-emitting element emitting white light. The light-emitting element according to an embodiment of the present disclosure may be embodied as a micro-LED.

Further, the plurality of light-emitting elements ED may further include redundant light-emitting elements ED1b, ED2b, and ED3b for a repair process. For example, the redundant light-emitting elements ED1b, ED2b, and ED3b may include the first redundant light-emitting element ED1b corresponding to the first light-emitting element ED1a, the second redundant light-emitting element ED2b corresponding to the second light-emitting element ED2a, and the third redundant light-emitting element ED3b corresponding to the third light-emitting element ED3a.

The wiring substrate M-SUB and the plurality of display units TU1 and TU2 may be bonded to each other via a plurality of bonding members BC1 and BC2 and may be electrically connected to each other via the plurality of bonding members BC1 and BC2. Each of the plurality of bonding members BC1 and BC2 may be disposed in each of the plurality of display units TU1 and TU2. The plurality of bonding members BC1 and BC2 may be disposed between the wiring substrate M-SUB and the plurality of display units TU1 and TU2. Each of the plurality of bonding members BC1 and BC2 may include a material having adhesive strength on at least one surface thereof. Further, each of the plurality of bonding members BC1 and BC2 may include a conductive material and thus may electrically connect the wiring substrate M-SUB and the plurality of display units TU1 and TU2 to each other.

For example, each of the bonding members BC1 and BC2 may include a spacer pattern 211, a conductive connection pattern 217, and an adhesive pattern 220. One surface of each of the bonding members BC1 and BC2 may be connected to a signal transfer line ML disposed on each of the display units TU1 and TU2, and the other surface thereof may be electrically connected to the link wiring line LL in the wiring substrate M-SUB.

For example, a filling material 230 may include a transparent epoxy resin and may fill a space between the wiring substrate M-SUB and the display units TU1 and TU2 in an underfill process. The filling material 230 together with the bonding members BC1 and BC2 may fix the wiring substrate M-SUB and the display units TU1 and TU2 to each other. Further, the filling material 230 may fill a bezel area as a boundary area between the display units TU1 and TU2 that are adjacent to each other. As the filling material 230 includes a transparent material, a seam area may be invisible to the user's field of view. Accordingly, a bezel area is minimum, reduced or substantially absent to realize a zero bezel area. Thus, an area size of the display area may be further increased.

Each of the plurality of display units TU1 and TU2 may include the light-emitting element ED disposed on the self-assembly substrate. This will be described with reference to FIG. 4 below. FIG. 4 shows only one sub-pixel among the plurality of sub-pixels for convenience of illustration.

Referring to FIG. 4, the wiring substrate M-SUB and the plurality of display units TU1 and TU2 may be bonded to each other via the plurality of bonding members BC1 and BC2 and may be electrically connected to each other via the plurality of bonding members BC1 and BC2.

The wiring substrate M-SUB may include the thin-film transistor TFT, the storage capacitor Cst and various lines disposed on the first base substrate 205. The thin-film transistor TFT may drive the light-emitting element ED, and the storage capacitor Cst may store a voltage therein so that the light-emitting element ED continues to maintain the same state during one frame. The first base substrate 205 may be made of a transparent material including glass or plastic.

A light-blocking layer LS may be disposed on the first base substrate 205 of the wiring substrate M-SUB. The light-blocking layer LS may prevent light incident from the first base substrate 205 from invading an active layer ACT of the thin-film transistor TFT to reduce leakage current.

A buffer layer 104 is disposed on the light-blocking layer LS. The buffer layer 104 may block impurities or moisture flowing through the first base substrate 205. The buffer layer 104 may include, for example, an insulating material such as silicon oxide (SiOx) or silicon nitride (SiNx).

The thin-film transistor TFT is disposed on the buffer layer 104. The thin-film transistor TFT may include the semiconductor layer ACT, a gate electrode GE, a source electrode SE, and a drain electrode DE. A gate insulating layer GI may be disposed between the semiconductor layer ACT and the gate electrode GE.

The semiconductor layer ACT may include an active area overlapping the gate electrode GE to constitute a channel, and a source area and a drain area located respectively on both opposing sides of the active area disposed therebetween. An interlayer insulating film 106 is disposed on the gate electrode GE. The interlayer insulating film 106 may receive a source contact SC and a drain contact DC therein. The source contact SC and the drain contact DC may contact portions of surfaces of the source area and the drain area of the semiconductor layer ACT, respectively. The source contact SC and the drain contact DC may be respectively electrically connected to the source electrode SE and the drain electrode DE located on the interlayer insulating film 106. Thus, the source electrode SE and the drain electrode DE may be respectively electrically connected to the source and drain areas of the semiconductor layer ACT via the source contact SC and the drain contact DC. Each of the source electrode SE and the drain electrode DE may be made of a conductive material such as copper (Cu), aluminum (Al), molybdenum (Mo), nickel (Ni), titanium (Ti), chromium (Cr), or an alloy thereof. However, the present disclosure is not limited thereto.

The storage capacitor Cst may be disposed so as to be spaced apart from the thin-film transistor TFT, and may include a first capacitor electrode ST1 and a second capacitor electrode ST2. The first capacitor electrode ST1 may be disposed between the first base substrate 205 and the buffer layer 104. The first capacitor electrode ST1 may be formed integrally with the light-blocking layer LS. The buffer layer 104 and the gate insulating layer GI may be disposed on the first capacitor electrode ST1 and may act as a dielectric layer. The second capacitor electrode ST2 may be disposed on the gate insulating layer GI. The second capacitor electrode ST2 may be made of the same material as that of the gate electrode GE.

A first passivation layer 108 is disposed on the source electrode SE and the drain electrode DE. The first passivation layer 108 serves to protect the thin-film transistor TFT and may include an insulating material. A first planarization layer 110 is disposed on the first passivation layer 108. The first planarization layer 110 serves to remove a surface step caused by an underlying component such as the thin-film transistor TFT. The first planarization layer 110 may include a photoactive compound (PAC). However, the present disclosure is not limited thereto.

A via-hole 112 may extend through the first planarization layer 110 and the first passivation layer 108 so as to expose a portion of the surface of the drain electrode DE.

A second passivation layer 116 including an insulating material may be disposed on the first planarization layer 110. A second via contact 120 may fill the via-hole 112. A connection electrode 125 may be disposed on the second passivation layer 116 so as to contact and be connected to the second via contact 120. A low resistance metal pattern 126 may cover the connection electrode 125.

One surface of the second via contact 120 may be connected to the drain electrode DE and the other surface thereof may be connected to the connection electrode 125. Further, the drain electrode DE may be electrically connected to the light-blocking layer LS via a first via contact VC extending through the interlayer insulating film 106 and the buffer layer 104. The low resistance metal pattern 126 and a protective layer 135 may be formed to cover the connection electrode 125 and may not cover a portion of a surface of the connection electrode 125 so as to make it be exposed.

The link wiring line LL may be disposed on the first planarization layer 110. The link wiring line LL may transfer various signals transmitted from the driver including the printed circuit board 215 to the plurality of signal transfer lines ML of each of the plurality of display units TU.

In an embodiment of the present disclosure, an example in which the link wiring line LL is disposed on the first planarization layer 110 is shown. However, the present disclosure is not limited thereto. For example, the link wiring line LL may be disposed on the first base substrate 205, and may include the same material as that of the light-blocking layer LS and may be coplanar with the light-blocking layer LS.

The link wiring line LL may be covered with a second planarization layer 140. The second planarization layer 140 may have a thickness sufficient to remove a surface step caused by an underlying circuit element such as the thin-film transistor TFT. The second planarization layer 140 may have a third via contact IML positioned therein. The third via contact IML may extend through a portion of the second planarization layer 140. One surface of the third via contact IML may be connected to a portion of a surface of the link wiring line LL, while the other surface of the third via contact IML may not be covered with the second planarization layer 140 so as to be exposed.

The second planarization layer 140 may further have an opening 145 therein. The opening 145 may extend through the second planarization layer 140 and the protective layer 135 so as to expose a portion of the surface of the connection electrode 125. The first line electrode CE1 and the second line electrode CE2 may be disposed on the second planarization layer 140. The first line electrode CE1 and the second line electrode CE2 may be spaced apart from each other. The second line electrode CE2 may extend along and on an exposed surface of the opening 145 and may be electrically connected to the drain electrode DE via the connection electrode 125.

The first line electrode CE1 and the second line electrode CE2 may be disposed on the same layer and may be made of the same conductive material. In one example, each of the first line electrode CE1 and the second line electrode CE2 may include a transparent metal oxide such as indium-tin-oxide (ITO) or indium-zinc-oxide (IZO). However, the present disclosure is not limited thereto.

Referring back to FIG. 4, the display unit TU is disposed so as to face the wiring substrate M-SUB in which the thin-film transistor TFT is disposed.

The display unit TU may act as a self-assembly substrate. The self-assembly substrate may include a second base substrate 102, and assembly electrodes AE1 and AE2, clad electrodes CDE1 and CDE2, a partitioning wall pattern PL defining or adjacent to an assembly pocket area PK, and the signal line ML which are disposed on the second base substrate 102.

The second base substrate 102 may include glass or plastic material. The assembly electrodes AE1 and AE2 may include the first assembly electrode AE1 and the second assembly electrode AE2. The first assembly electrode AE1 and the second assembly electrode AE2 may be spaced apart from each other and may correspond to each of the plurality of light-emitting elements ED assembled in a self-assembly process. Each of the assembly electrodes AE1 and AE2 may include a transparent electrode material including indium-tin-oxide (ITO). When voltage is applied to the first assembly electrode AE1 and the second assembly electrode AE2 in the self-assembly process, the first assembly electrode AE1 and the second assembly electrode AE2 can generate an electric field therebetween so as to stably fix the light-emitting element ED which has moved into the assembly pocket PK.

The first assembly electrode AE1 and the second assembly electrode AE2 are covered with the clad electrodes CDE1 and CDE2, respectively. The clad electrodes CDE1 and CDE2 include the first clad electrode CDE1 and the second clad electrode CDE2 which are disposed to cover the first assembly electrode AE1 and the second assembly electrode AE2, respectively.

The first clad electrode CDE1 and the second clad electrode CDE2 may prevent corrosion of the first assembly electrode AE1 and the second assembly electrode AE2 in the self-assembly process performed in fluid, and may allow the electric field for the assembly of the light-emitting element ED to be easily generated. Each of the first clad electrode CDE1 and the second clad electrode CDE2 may include copper (Cu). A spacing between the first clad electrode CDE1 and the second clad electrode CDE2 may be smaller than, for example, a spacing between the first assembly electrode AE1 and the second assembly electrode AE2, such that the assembly position of the light-emitting element ED disposed in the assembly pocket PK may be fixed more precisely.

The partitioning wall PL may be disposed on the clad electrodes CDE1 and CDE2. A portion of the partitioning wall PL may cover a top surface of each of the clad electrodes CDE1 and CDE2, and the remaining portion thereof may be disposed on the second base substrate 102. The partitioning wall PL has the assembly pocket PK defined or included therein. The assembly pocket PK may designate a position where the light-emitting element ED is fixedly disposed. The partitioning wall PL may have a thickness equal to or higher than a height of the light-emitting element ED.

An adhesive layer AD is disposed on the clad electrodes CDE1 and CDE2. The adhesive layer AD serves to adhere the light-emitting element ED to the substrate 102. The adhesive layer AD may be made of a thermally-curable material or an optically-curable material. However, the present disclosure is not limited thereto.

The light-emitting element ED may be disposed on the adhesive layer AD. The light-emitting element ED according to an embodiment of the present disclosure may be embodied as a micro-LED. The micro-LED may refer to an LED made of an inorganic material and may be a light-emitting element of 100 μm or smaller. Further, in an embodiment of the present disclosure, a lateral type micro-LED is shown by way of example. However, the present disclosure is not limited thereto. For example, the light-emitting element may be embodied as a flip chip-shaped micro-LED or a nanorod-shaped micro-LED.

The light-emitting element ED may include a nitride semiconductor structure NSS, a first electrode E1 and a second electrode E2. The nitride semiconductor structure NSS may include a first semiconductor layer NS1, an active layer EL disposed on one side of the first semiconductor layer NS1, and a second semiconductor layer NS2 disposed on the active layer EL. The first electrode E1 is disposed on an area of the first semiconductor layer NS1 where the active layer EL is not disposed, while the second electrode E2 is disposed on the second semiconductor layer NS2.

The first semiconductor layer NS1 may be a layer for supplying electrons to the active layer EL, and may include a nitride semiconductor containing first conductivity type impurities. For example, the first conductivity-type impurity may include an N-type impurity. The active layer EL disposed on one side of the first semiconductor layer NS1 may have a multi-quantum well (MQW). The second semiconductor layer NS2 may be a layer for injecting holes into the active layer EL. The second semiconductor layer NS2 may include a nitride semiconductor containing second conductivity type impurities. For example, the second conductivity type impurity may include a P type impurity.

A protective layer pattern PT may cover an outer side surface of the light-emitting element ED. The protective layer pattern PT serves to prevent damage that may occur on a side surface of the nitride semiconductor structure NSS in a dry etching process to form the nitride semiconductor structure NSS to supplement the characteristics of the element.

The other surface of the first semiconductor layer NS1 which is opposite to one surface of the first semiconductor layer NS1 of the light-emitting element ED on which the active layer EL is disposed may contact and be fixed to the adhesive layer AD. Accordingly, the first electrode E1 and the second electrode E2 of the light-emitting element ED may face and be electrically connected to the first line electrode CE1 and the second line electrode CE2 of the wiring substrate M-SUB, respectively.

The signal transfer line ML may be disposed on the second base substrate 102 of the display unit TU. The signal transfer line ML may be coplanar with the assembly electrodes AE1 and AE2. However, the present disclosure is not limited thereto. The signal transfer line ML may include a plurality of signal transfer lines. For example, the plurality of signal transfer lines ML may include a plurality of scan lines, a plurality of high-potential power lines, a plurality of data lines, and a plurality of reference voltage lines. The plurality of signal transfer lines ML may be disposed in the same plane and on the second base substrate 102. Further, each of the plurality of signal transfer line ML may be made of the same material as that of each of the assembly electrodes AE1 and AE2.

The wiring substrate M-SUB in which the thin-film transistor TFT is disposed and each of the plurality of display units TU in which the plurality of light-emitting elements ED are disposed may be bonded to each other via each of the plurality of bonding members BC, and may be electrically connected to each other via each of the plurality of bonding members BC.

One surface of the bonding member BC may be connected to the link wiring line LL via the third via contact IML of the wiring substrate M-SUB, and the other surface of the bonding member BC may be electrically connected to the signal transfer line ML of the display unit TU. The bonding member BC may include the spacer pattern 211, the conductive connection pattern 217, and the adhesive pattern 220.

The spacer pattern 211 may play a role of maintaining a gap between the wiring substrate M-SUB and the display unit TU. The spacer pattern 211 may have a reverse taper shape in which a width of one surface thereof in contact with the third via contact IML is larger than that of the other surface thereof. However, the present disclosure is not limited thereto.

An outer side surface of the spacer pattern 211 may be covered with the conductive connection pattern 217. For example, the conductive connection pattern 217 may cover an upper surface of the spacer pattern 211 and surround an outer side surface of the spacer pattern 211. The conductive connection patter 217 may be disposed to surround at least an outer surface of the spacer pattern 211. Further, the conductive connection pattern 217 may contact the third via contact IML. The conductive connection pattern 217 may be made of a conductive material such as copper (Cu), aluminum (Al), molybdenum (Mo), nickel (Ni), titanium (Ti), chromium (Cr), or an alloy thereof. However, the present disclosure is not limited thereto.

The adhesive pattern 220 may be disposed on the conductive connection pattern 217. The adhesive pattern 220 may bond and fix the wiring substrate M-SUB and the display unit TU to each other. Further, the adhesive pattern 220 may have electrical conductivity to transmit a signal transmitted to the link wiring line LL of the wiring substrate M-SUB to the display unit TU. To this end, the adhesive pattern 220 may include a material having electrical conductivity and adhesiveness. For example, the adhesive pattern 220 may include an anisotropic conductive film (ACF).

A space between the wiring substrate M-SUB and the display unit TU and a boundary area between adjacent display units may be filled with the transparent filling material 230. The filling material 230 may improve the bonding strength between wiring substrate M-SUB and the display unit TU. Further, the boundary area between adjacent display units may be filled with the transparent filling material 230, such that the bezel area may be minimum, reduced or may be substantially absent to realize no bezel area.

According to an embodiment of the present disclosure, the self-assembly substrate on which the light-emitting element ED is disposed may be embodied as the display unit TU and may be directly bonded onto the wiring substrate M-SUB, such that a process step of transferring the light-emitting element may be omitted, thereby realizing process optimization. Further, the process step of transferring the light-emitting element may be omitted to prevent a decrease in the transfer yield or a misalignment problem in the transfer process.

Further, the display unit in which the light-emitting element is disposed may be directly bonded to the wiring substrate, such that use of a transfer substrate as a temporary substrate for transferring the light-emitting element may be omitted, thereby unifying parts and thus manufacturing an eco-friendly product.

In the display device according to one embodiment of the present disclosure, the light-emitting element ED may be disposed in the display unit TU, and the thin-film transistor TFT may be disposed in the wiring substrate M-SUB. Accordingly, even when a defect occurs in the light-emitting element ED, only the display unit TU in which the light-emitting element ED is disposed may be replaced, such that process optimization may be realized.

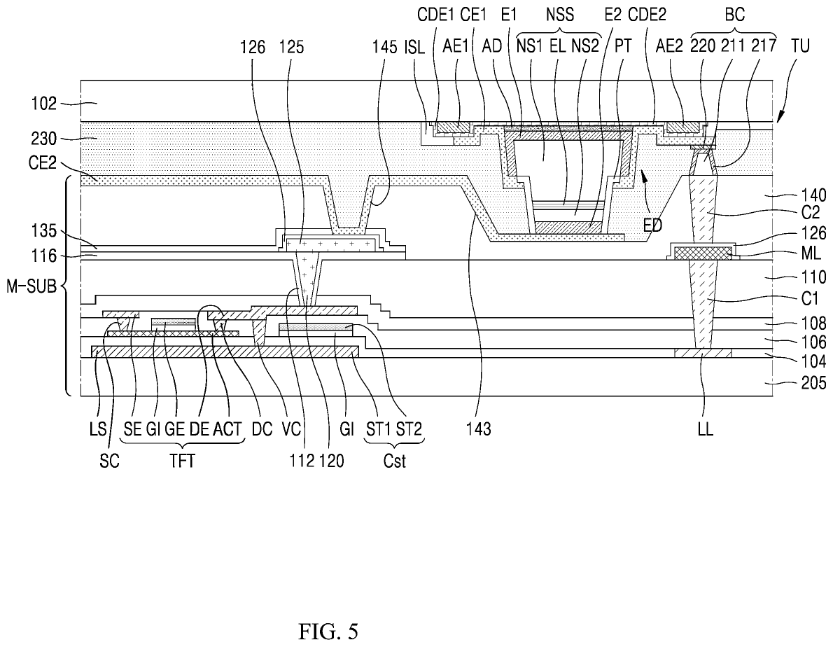

In an embodiment of the present disclosure, the display device in which the lateral type micro LED is disposed has been described. However, the display device may include a vertical type micro LED. This will be described with reference to FIG. 5 below.

FIG. 5 is a cross-sectional view showing a modified example of a display device according to one embodiment of the present disclosure. The display device according to FIG. 5 is the same as the display device according to FIG. 4 except for a configuration in which the light-emitting element ED is the vertical micro-LED. Thus, differences therebetween are mainly described, and the same components are briefly described or descriptions thereof may be omitted.

Referring to FIG. 5, the thin-film transistor TFT may be disposed in the wiring substrate M-SUB. The first passivation layer 108 and the first planarization layer 110 may be disposed on the thin-film transistor TFT. The connection electrode 125 and the signal transfer line ML may be disposed on the first planarization layer 110. A low resistance metal pattern 126 may be disposed on the signal transfer line ML and the connection electrode 125. The protective layer 135 may be disposed on the connection electrode 125 and the second passivation layer 116. The protective layer 135 may not cover a portion of a surface of the low resistance metal pattern 126 so as to make it be exposed.

The link wiring line LL may be disposed on the first base substrate 205 of the wiring substrate M-SUB. The link wiring line LL may be coplanar with the light-blocking layer LS. However, the present disclosure is not limited thereto. The link wiring line LL and the signal transfer line ML may be electrically connected to each other via a first through-electrode C1 extending through the first planarization layer 110, the first passivation layer 108, and the interlayer insulating film 106.

The low resistance metal pattern 126 and the signal transfer line ML may be connected to the second through-electrode C2 extending through the second planarization layer 140. The second through-electrode C2 may contact the bonding member BC which will be described later and thus may be electrically connected to the light-emitting element ED. The second planarization layer 140 may have a groove 143 and an opening 145 positioned therein. The groove 143 may have an inclined side surface and a bottom surface. The second line electrode CE2 may be disposed on the second planarization layer 140 having the groove 143 and the opening 145 positioned therein. The second line electrode CE2 may contact a portion of the low resistance metal pattern 126 exposed through the opening 145 and thus may be electrically connected to the connection electrode 125. Further, the second line electrode CE2 may extend on and along an exposed surface of each of the opening 145 and the groove 143 and thus may be connected to the second electrode E2 of the light-emitting element ED disposed in the groove 143.

The display unit TU including the light-emitting element ED is disposed so as to face the wiring substrate M-SUB including the thin-film transistor TFT. The display unit TU includes the second base substrate 102, and the first assembly electrode AE1, the second assembly electrode AE2, the first clad electrode CDE1, the second clad electrode CDE2, the first line electrode CE1, the adhesive layer AD, and an insulating isolation layer ISL which are disposed on the second base substrate 102. The insulating isolation layer ISL serves to insulate the first clad electrode CDE1 and the second clad electrode CDE2. Further, the present disclosure shows the insulating isolation layer ISL. However, the present disclosure is not limited thereto. For example, as shown in FIG. 4, the partitioning wall PL defining or including the assembly pocket PK designating a location where the light-emitting element ED is disposed may be disposed.

The light-emitting element ED may be disposed on the adhesive layer AD. The light-emitting element ED may be embodied as the vertical micro-LED. The light-emitting element ED may include the nitride semiconductor structure NSS, the first electrode E1 and the second electrode E2. The nitride semiconductor structure NSS may include a structure in which the first semiconductor layer NS1, the active layer EL, and the second semiconductor layer NS2 are vertically stacked. The protective layer pattern PT may be disposed on an outer side surface of the nitride semiconductor structure NSS.

The first electrode E1 may be disposed on at least one surface of the first semiconductor layer NS1 in contact with the adhesive layer AD. For example, the first electrode E1 may extend along and on one surface of the first semiconductor layer NS1 and along and on a portion of a side surface of the first semiconductor layer NS1. The first line electrode CE1 may be disposed so as to be in contact with an outer side surface of the first electrode E1. The second electrode E2 may be disposed so as to be in contact with one surface of the second semiconductor layer NS2. The second electrode E2 may be disposed so as to be in contact with the second line electrode CE2.

The wiring substrate M-SUB in which the thin-film transistor TFT is disposed and each of the plurality of display units TU in which the plurality of light-emitting elements ED are disposed may be bonded to each other via each of the plurality of bonding members BC, and may be electrically connected to each other via each of the plurality of bonding members BC.

One surface of the bonding member BC may contact the second through-electrode C2 of the wiring substrate M-SUB, while the other surface of the bonding member BC may contact the first line electrode CE1. As a result, the second through-electrode C2 of the wiring substrate M-SUB may be connected to the link wiring line LL via the bonding member BC. The bonding member BC may include the spacer pattern 211, the conductive connection pattern 217, and the adhesive pattern 220.

The space between the wiring substrate M-SUB and the display unit TU may be filled with the transparent filling material 230. The filling material 230 may improve the bonding strength between wiring substrate M-SUB and the display unit TU.

A defect may occur in a process of manufacturing a part disposed in the display unit TU. As the individual display unit TU is bonded to the wiring substrate M-SUB via the bonding member BC, only the display unit having a defective part among the plurality of display units may be replaced. Accordingly, the repair process may be easily performed and thus the process optimization may be implemented.

Further, the light-emitting element ED is disposed in the display unit TU, while the thin-film transistor TFT is disposed in the wiring substrate M-SUB. Thus, even when a defect occurs in the light-emitting element ED, a non-defective thin-film transistor TFT may not be replaced but be used. This may prevent an unnecessary increase in the number of manufacturing process steps.

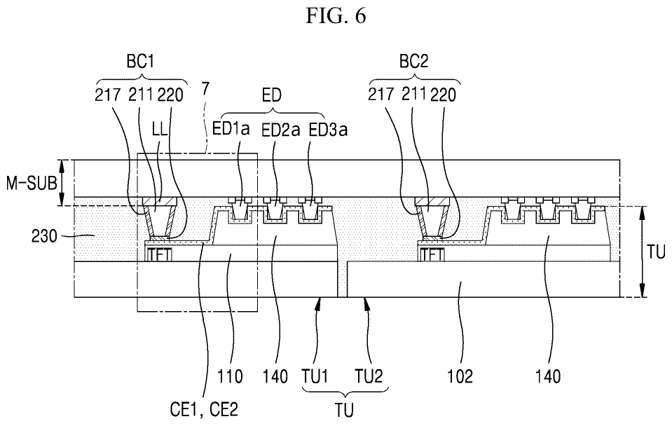

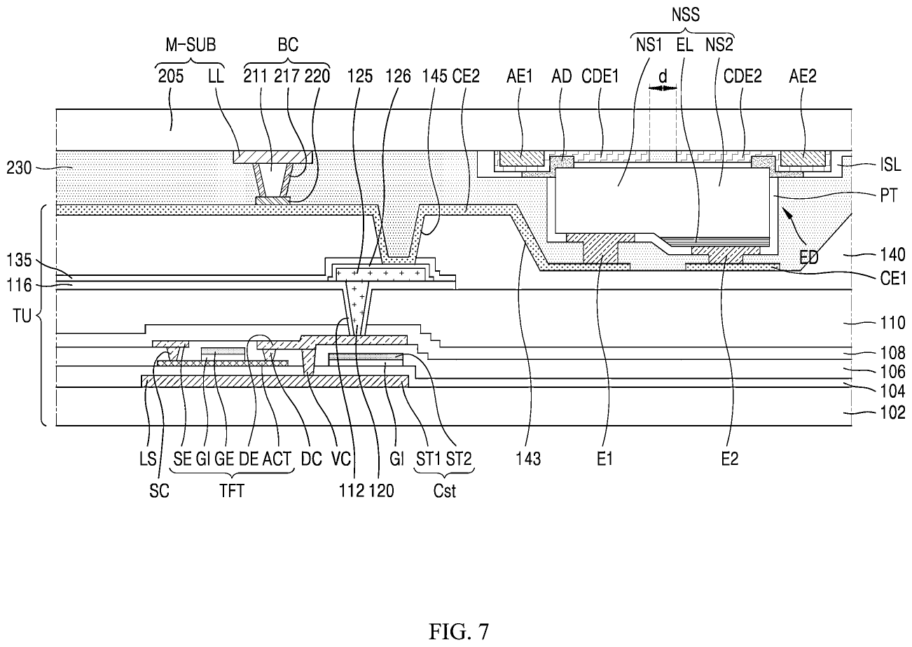

FIG. 6 is a schematic cross-sectional view of a display device according to another embodiment of the present disclosure. FIG. 7 is a cross-sectional view of 7 of FIG. 6 of the display device according to another embodiment of the present disclosure. In this regard, the same reference numerals as those in FIGS. 1 to 5 denote the same components. The same components may be briefly described or the descriptions thereof may be omitted.

Referring to FIG. 6 and FIG. 7, the thin-film transistor TFT may be disposed in the display unit TU, while the light-emitting element ED may be disposed on the wiring substrate M-SUB. The display unit TU and the wiring substrate M-SUB may be bonded to each other via the bonding member BC.

The first passivation layer 108 and the first planarization layer 110 may be disposed on the thin-film transistor TFT disposed in the display unit TU. The connection electrode 125, the low resistance metal pattern 126, and the protective layer 135 may be disposed on the first planarization layer 110. The protective layer 135 may not cover a portion of the surface of the low resistance metal pattern 126 so as to make it be exposed.

The second planarization layer 140 may have the groove 143 and the opening 145 positioned therein. The first line electrode CE1 and the second line electrode CE2 may be disposed on the second planarization layer 140 having the groove 143 and the opening 145 positioned therein. The second line electrode CE2 may contact a portion of the low resistance metal pattern 126 exposed through the opening 145 and thus may be electrically connected to the connection electrode 125. Further, the second line electrode CE2 may extend on and along an exposed surface of each of the opening 145 and the groove 143 and thus may be connected to the first electrode E1 of the light-emitting element ED disposed in the groove 143. The second line electrode CE2 may be spaced apart from the first line electrode CE1 by a predetermined or selected distance.

The display unit TU including the thin-film transistor TFT is disposed so as to face the wiring substrate M-SUB including the light-emitting element ED.

The wiring substrate M-SUB includes the first base substrate 205, and the first assembly electrode AE1, the second assembly electrode AE2, the first clad electrode CDE1, the second clad electrode CDE2, the first line electrode CE1, the adhesive layer AD, and the insulating isolation layer ISL which are disposed on the first base substrate 205. Further, the present disclosure shows the insulating isolation layer ISL. However, the present disclosure is not limited thereto. For example, as shown in FIG. 4, the partitioning wall PL defining or including the assembly pocket PK designating a location where the light-emitting element ED is disposed may be disposed.

The light-emitting element ED may be disposed on the adhesive layer AD. The light-emitting element ED may include the nitride semiconductor structure NSS including the first semiconductor layer NS1, the active layer EL and the second semiconductor layer NS2, the first electrode E1 disposed on the first semiconductor layer NS1, and the second electrode E2 disposed on the second semiconductor layer NS2. The protective layer pattern PT may be disposed on an outer side surface of the nitride semiconductor structure NSS.

The light-emitting element ED may be embodied as a horizontal or lateral type micro-LED. However, the present disclosure is not limited thereto. For example, the light-emitting element ED may be embodied as a vertical type micro-LED, a flip-chip type micro-LED, or a nanorod-shaped micro-LED.

A spacing d between the first clad electrode CDE1 and the second clad electrode CDE2 may be smaller than, for example, a spacing between the first assembly electrode AE1 and the second assembly electrode AE2. Thus, when an electric field is generated for the self-assembly, the assembly position of the light-emitting element ED may be fixed more precisely.

The link wiring line LL may be disposed on the first base substrate 205 of the wiring substrate M-SUB. The bonding member BC may be disposed on the link wiring line LL so as to electrically connect the display unit TU and the wiring substrate M-SUB to each other. The wiring substrate M-SUB on which the plurality of light-emitting elements ED is disposed and each of the plurality of display units TU in which the plurality of thin-film transistors TFT are disposed may be bonded to each other via each of the plurality of bonding members BC.

One surface of each bonding member BC may contact the link wiring line LL of the wiring substrate M-SUB, while the other surface of the bonding member BC may contact the second line electrode CE2 of the display unit TU. As a result, the second line electrode CE2 of the display unit TU may be connected to the link wiring line LL via the bonding member BC. The bonding member BC may include the spacer pattern 211, the conductive connection pattern 217, and the adhesive pattern 220.

The space between the wiring substrate M-SUB and the display unit TU may be filled with the transparent filling material 230. The filling material 230 may improve the bonding strength between the wiring substrate M-SUB and the display unit TU.

In the display device according to another embodiment of the present disclosure, the light-emitting element ED is disposed on the wiring substrate M-SUB, while the thin-film transistor TFT is disposed in the display unit TU. Accordingly, when a defect occurs in the thin-film transistor TFT, only the display unit TU in which the defective thin-film transistor TFT is disposed may be replaced and repaired. Thus, the process optimization may be realized.

In the display unit TU which includes both the thin-film transistor TFT and the light-emitting element ED, when only one of the thin-film transistor TFT and the light-emitting element ED is defective, both the thin-film transistor TFT and the light-emitting element ED should be removed. However, according to the embodiment of the present disclosure, a normal one of the thin-film transistor TFT and the light-emitting element ED may not be removed. Thus, the unnecessary increase in the number of the process steps may be prevented and thus the process optimization may be implemented.

Further, the use of harmful chemical materials in proceeding with unnecessary process steps may be prevented, which has the effect of realizing the eco-friendly product.

Although the embodiments of the present disclosure have been described in more detail with reference to the accompanying drawings, the present disclosure is not necessarily limited to these embodiments, and may be modified in a various manner within the scope of the technical spirit of the present disclosure. Accordingly, the embodiments as disclosed in the present disclosure are intended to describe rather than limit the technical idea of the present disclosure, and the scope of the technical idea of the present disclosure is not limited by these embodiments. Therefore, it should be understood that the embodiments described above are not restrictive but illustrative in all respects.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments inlightofthe above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a wiring substrate;
a plurality of link wiring lines disposed in the wiring substrate;
a plurality of display units disposed on the wiring substrate and spaced apart from each other; and
a plurality of bonding members positioned between the plurality of display units and the wiring substrate, wherein the plurality of bonding members are respectively connected to the plurality of link wiring lines,
wherein the wiring substrate includes a thin-film transistor, and
wherein each of the plurality of display units includes a light-emitting element.

2. The display device of claim 1, wherein the wiring substrate include a single sheet substrate, and
wherein the plurality of display units are disposed on the wiring substrate and are arranged so as to be spaced apart from each other in each of first and second directions traverse each other.

3. The display device of claim 1, wherein the wiring substrate includes:
a first base substrate;
a light-blocking layer disposed on the first base substrate;
the thin-film transistor disposed on the light-blocking layer, wherein the thin-film transistor includes a semiconductor layer, a gate electrode, a source electrode, and a drain electrode;
a first via contact for electrically connecting the drain electrode and the light-blocking layer to each other;
a first planarization layer covering the thin-film transistor on the first base substrate;
a second via contact that extends through the first planarization layer so as to be connected to the drain electrode;
a connection electrode electrically connected to the second via contact;
a second planarization layer having an opening therein exposing a portion of a surface of the connection electrode;
a first line electrode disposed on the second planarization layer; and
a second line electrode disposed on the second planarization layer and spaced apart from the first line electrode, wherein the second line electrode extends along and on an exposed surface of the opening and is electrically connected to the drain electrode via the connection electrode.

4. The display device of claim 1, wherein each of the plurality of display units includes:
a second base substrate made of a transparent material;
a first assembly electrode disposed on the second base substrate;
a second assembly electrode disposed on the second base substrate and spaced apart from the first assembly electrode;
a first clad electrode covering the first assembly electrode;
a second clad electrode covering the second assembly electrode; and
a partitioning wall having a portion covering each of the first and second clad electrodes, and a remaining portion disposed on the second base substrate, wherein the partitioning wall includes an assembly pocket, wherein the light-emitting element is in the assembly pocket.

5. The display device of claim 4, wherein a spacing between the first clad electrode and the second clad electrode is smaller than a spacing between the first assembly electrode and the second assembly electrode.

6. The display device of claim 3, wherein the light-emitting element is electrically connected to the first line electrode and the second line electrode of the wiring substrate.

7. The display device of claim 4, wherein the light-emitting element is electrically connected to a first line electrode and a second line electrode of the wiring substrate.

8. The display device of claim 4, wherein the partitioning wall has a thickness equal to or greater than a height of the light-emitting element.

9. The display device of claim 1, further comprising a filling material disposed between the wiring substrate and the plurality of display units, wherein the filling material includes a transparent resin.

10. The display device of claim 1, wherein each of the bonding members includes:
a spacer pattern having one surface contacting the wiring substrate;
a conductive connection pattern covering at least an outer side surface of the spacer pattern; and
an adhesive pattern disposed on the other surface of the spacer pattern and contacting the conductive connection pattern, wherein the adhesive pattern is connected to each display unit.

11. A display device, comprising:
a wiring substrate;
a plurality of link wiring lines disposed in the wiring substrate;
a plurality of display units disposed on the wiring substrate and spaced apart from each other; and
a plurality of bonding members disposed between the plurality of display units and the wiring substrate, wherein the plurality of bonding members are respectively connected to the plurality of link wiring lines,
wherein the wiring substrate includes a light-emitting element, and
wherein each of the plurality of display units includes a thin-film transistor.

12. The display device of claim 11, wherein each of the plurality of display units includes:
a second base substrate;
a light-blocking layer disposed on the second base substrate;
a thin-film transistor disposed on the light-blocking layer and including a semiconductor layer, a gate electrode, a source electrode, and a drain electrode;
a first via contact for electrically connecting the drain electrode and the light-blocking layer to each other;
a first planarization layer covering the thin-film transistor on the second base substrate;
a second via contact that extends through the first planarization layer so as to be connected to the drain electrode;
a connection electrode electrically connected to the second via contact;
a second planarization layer having an opening therein exposing a portion of a surface of the connection electrode;
a first line electrode disposed on the second planarization layer; and
a second line electrode disposed on the second planarization layer and spaced apart from the first line electrode, wherein the second line electrode extends along and on an exposed surface of the opening and is electrically connected to the drain electrode via the connection electrode.

13. The display device of claim 11, wherein the wiring substrate includes:
a first base substrate made of a transparent material;
a first assembly electrode disposed on the first base substrate;
a second assembly electrode disposed on the first base substrate and spaced apart from the first assembly electrode;
a first clad electrode covering the first assembly electrode;
a second clad electrode covering the second assembly electrode; and
an adhesive layer disposed on each of the first and second clad electrodes so as to designate a position where the light-emitting element is disposed.

14. The display device of claim 13, wherein a spacing between the first clad electrode and the second clad electrode is smaller than a spacing between the first assembly electrode and the second assembly electrode.

15. The display device of claim 12, wherein the light-emitting element is electrically connected to the first line electrode and the second line electrode of the respective display unit.

16. The display device of claim 11, further comprising a filling material disposed between the wiring substrate and the plurality of display units, wherein the filling material includes a transparent resin.

17. The display device of claim 11, wherein each of the bonding members includes:
a spacer pattern having one surface contacting each link wiring line of the wiring substrate;
a conductive connection pattern covering an outer side surface of the spacer pattern; and
an adhesive pattern disposed on the other surface of the spacer pattern and contacting the conductive connection pattern, wherein the adhesive pattern is connected to each display unit.

18. A display device, comprising:
a wiring substrate;
a plurality of link wiring lines disposed in the wiring substrate;
a self-assembly substrate disposed on the wiring substrate;
a plurality of light-emitting elements disposed on the self-assembly substrate; and
a plurality of bonding members disposed between the self-assembly substrate and the wiring substrate to bond and electrically connect the self-assembly substrate and the wiring substrate to each other, wherein the plurality of bonding members are respectively connected to the plurality of link wiring lines,
wherein the wiring substrate includes a thin-film transistor.

19. The display device of claim 18, wherein the self-assembly substrate is disposed as a plurality of display units, and wherein each of the plurality of display units is bonded and electrically connected to each other via each of the plurality of bonding members.

20. The display device of claim 18, wherein the plurality of light-emitting elements includes redundant light-emitting elements.
